(19) United States
(12) Patent Application Publication
(10) Pub. No.: US 2026/0033116 A1
(43) Pub. Date: Jan. 29, 2026

(54) POWER EFFICIENT MICRO-LED ARCHITECTURES

(71) Applicant: Intel Corporation, Santa Clara, CA (US)

(72) Inventors: Paul West, Portland, OR (US); Yingfei Lin; Ronald C. Woodbeck, Placerville, CA (US); Khaled Ahmed, San Jose, CA (US)

(73) Assignee: Intel Corporation, Santa Clara, CA (US)

(21) Appl. No.: 18/993,451

(22) PCT Filed: Aug. 12, 2022
(86) PCT No.: PCT/CN2022/112220

§ 371 Date: Jan. 10, 2025

(51) Int. Cl. H10H 29/856; H10H 29/37

(52) U.S. Cl. CPC H10H 29/856; H10H 29/37

(57) ABSTRACT

In one embodiment, an apparatus includes a thin film transistor (TFT) structure layer, a dielectric layer on the TFT structure layer, and an anode on the dielectric layer and in electrical connection with the TFT structure layer. The apparatus also includes a light emitting material on the anode and a reflective material layer surrounding the light emitting material. The apparatus further includes a cathode on the light emitting material.

### BACKGROUND

Organic light emitting diode (OLED) displays are prevalent in the market today. OLED displays include a pixel separator or pixel define layer (PDL) in each sub-pixel that is used to define the size and location of the light emitting material of the sub-pixel and serves an additional function of absorbing light to prevent it from spreading into adjacent sub-pixels. Micro-LEDs present an interesting alternative to OLED displays, as the offer a potentially longer lifetime advantage and can potentially display brighter images than OLED displays.

### BRIEF DESCRIPTION OF THE DRAWINGS

FIG. 1 illustrates an example uLED sub-pixel architecture that may be found in current uLED-based displays.

FIG. 2 illustrates an example uLED sub-pixel architecture with no via or trench in accordance with embodiments of the present disclosure.

FIGS. 3A-3B and 4-5 illustrate example uLED sub-pixel architectures with reflecting sidewalls in accordance with embodiments of the present disclosure.

FIGS. 6A-6B and 7A-7B illustrate example uLED sub-pixel architectures with white or black photoresist material in accordance with embodiments of the present disclosure.

FIGS. 8A-8B illustrate example emissions from a conventional uLED and a uLED with a reflective layer in accordance with embodiments herein, respectively.

FIG. 9 is an example computing system comprising structures with LEDs electrically coupled to a mirror layer by vias or pillars

FIG. 10 is a block diagram of an example computing system in which technologies described herein may be implemented.

### DETAILED DESCRIPTION

The present disclosure provides various micro-LED (uLED) architectures that can provide brighter sub-pixel emissions and accordingly, more power efficient displays. In certain embodiments, uLED sub-pixels include reflecting sidewalls around each sub-pixel that can aid to increase the amount of light that is externally emitted from the sub-pixel (as opposed to being propagated or absorbed in adjacent materials) and prevent the light from mixing with light from other sub-pixels of the display. In other embodiments, uLED sub-pixels include a white photoresist material, a black photoresist material, or both around each sub-pixel to either reflect light (in the case of white photoresist) to enhance external emission of the light in a similar manner as the reflecting sidewalls previously described, or absorb light (in the case of black photoresist) to prevent the light emitted by the sub-pixel from mixing with other sub-pixels of the display. As used herein, a sub-pixel may refer to a portion of a pixel of a larger display. For instance, each pixel of a display (which may include millions of pixels) may include a red sub-pixel, a green sub-pixel, and a blue sub-pixel.

Embodiments herein may provide one or more advantages over existing uLED architectures. For example, certain embodiments may increase the efficiency of uLED-based displays (e.g., through an increase in the electrical-to-optical efficiency of the sub-pixels), reduce power consumption in products with such displays (e.g., due to the higher efficiency of the sub-pixels), eliminate undesirable light mixing between sub-pixels, and/or decrease the cost of manufacturing.

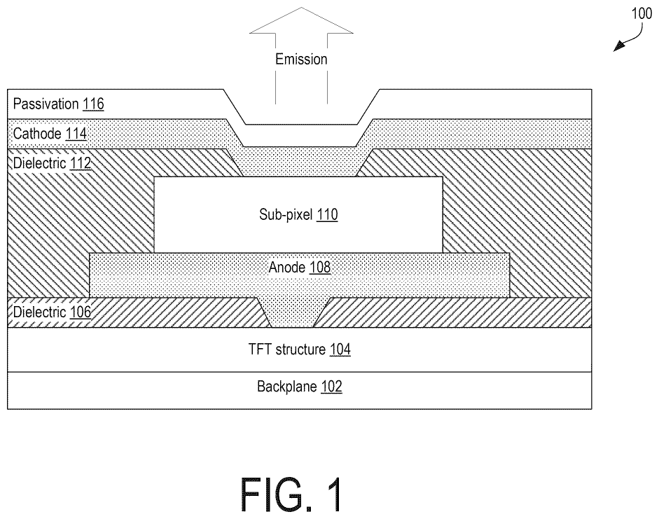

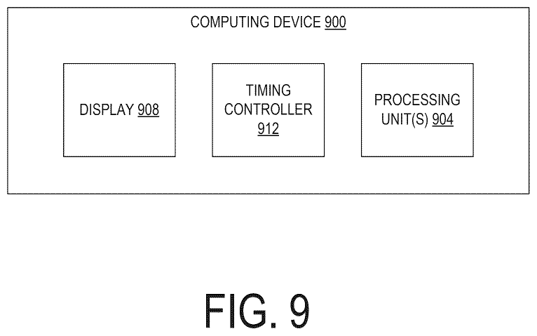

FIG. 1 illustrates an example uLED sub-pixel architecture 100 that may be found in current uLED-based displays. The example architecture 100 includes a backplane 102 that includes circuitry or other components to connect the sub-pixel architecture 100 to other circuitry, e.g., display control circuitry (e.g., a timing controller such as timing controller 912 of FIG. 9), and a thin film transistor (TFT) structure 104 on the backplane 102 that includes a TFT driver circuit for the sub-pixel. There is a dielectric layer 106 formed on the TFT structure 104, and an anode 108 formed on the dielectric layer 106. The anode 108 may be a conductive material, such as a metal or conductive oxide, and is electrically connects to the TFT structure 104 through an opening (which may be formed by an etching process) in the dielectric layer 106 as shown. There is a uLED sub-pixel material 110 formed on the anode 108, and a dielectric layer 112 surrounding the sub-pixel 110. The dielectric layer 112 may be the same or different material as the dielectric layer 106.

There is additionally a cathode 114 formed on the dielectric layer 112 that is electrically connected to the sub-pixel 110 through an opening (e.g., etched opening) in the dielectric layer 112. The cathode may be formed from an optically transparent or translucent material, e.g., a transparent conducting oxide (TCO), to allow light emitted by the sub-pixel 110 to escape (e.g., vertically in the example shown). Finally, there is a passivation layer 116 formed on the cathode layer 114 that can act to protect the underlying materials. In other embodiments, the layer 116 may include materials for performing other functions of the display (e.g., for materials that may be further deposited on top of the layer 116). The sub-pixel 110 may include a material that emits light of a certain wavelength (e.g., red, green, blue, or another color) based on voltage or current signals applied thereto. For instance, the TFT structure 104 may provide voltage or current signals (e.g., to the anode 108 and/or the cathode 114) that cause the sub-pixel material 110 to emit light, with the voltage signals being based on signals received from control circuitry in, or delivered by, the backplane 102.

As shown, in configuration, the cathode connection (and subsequent passivation layer) to the sub-pixel 110 is made through a dielectric layer through a via or trench. This can limit the cathode contact area to a subset of the total sub-pixel area, and may eliminate contact to undesirable (e.g., damaged) areas on the top edges or sides of the sub-pixel 110. Moreover, the remainder of the sub-pixel area is encapsulated in a dielectric space, which can provide electrical and physical protection to the sub-pixel 110. However, this configuration can also cause a lower portion of the emission from the sub-pixel 110 to escape from the architecture.

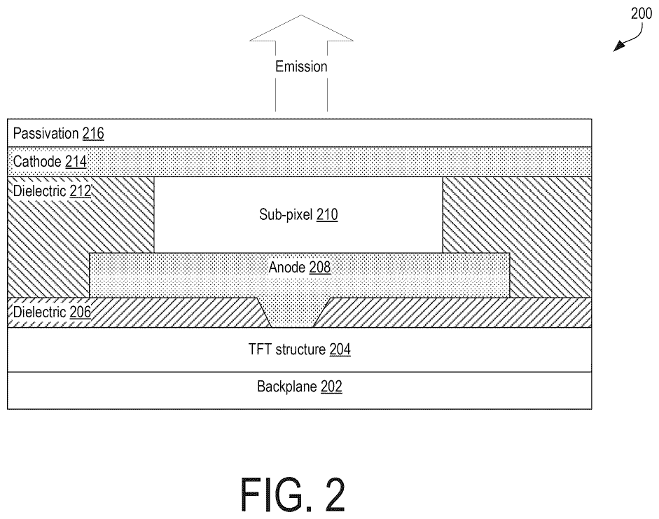

FIG. 2 illustrates an example uLED sub-pixel architecture 200 with no via or trench in accordance with embodiments of the present disclosure. The example architecture is similar to that shown in FIG. 1. That is, the backplane 202 is the same as or similar to the backplane 102, the TFT structure 204 is the same as or similar to the TFT structure 104, the dielectric layer 206 is the same as or similar to the dielectric layer 106, the anode 208 is the same as or similar to the anode 108, the sub-pixel 210 is the same as or similar to the sub-pixel 110, the dielectric layer 212 is the same as or similar to the dielectric layer 112, the cathode 214 is the same as or similar to the cathode 114, and the passivation layer 216 is the same as or similar to the passivation layer 116.

However, in the example shown, the cathode 214 and passivation layer 216 are planar/flat across the top side of the dielectric layer 212, causing the contact area between the cathode 214 and the sub-pixel 210 to be larger. This also causes the emission area for the sub-pixel 210 to be larger than that of the sub-pixel 110 of FIG. 1. This is due to the full contact area to the top of the sub-pixel 210, which provides more connections to the sub-pixel constituent components, as well as less resistance. In addition, there are fewer planar interfaces above the sub-pixel 210 that have fewer internal reflections, meaning a larger emission efficiency. The architecture 200 also provides a more simplified stack, requiring fewer and more simple processing steps (e.g., no cathode lithography steps are required as with the architecture 100).

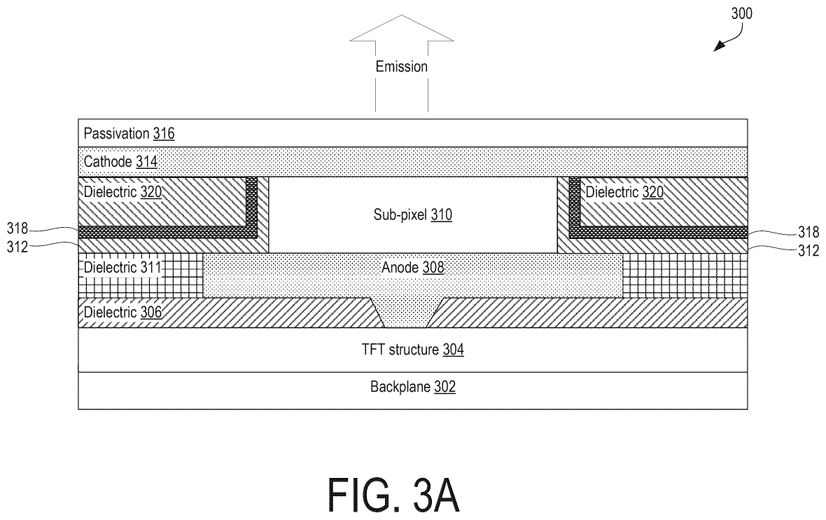

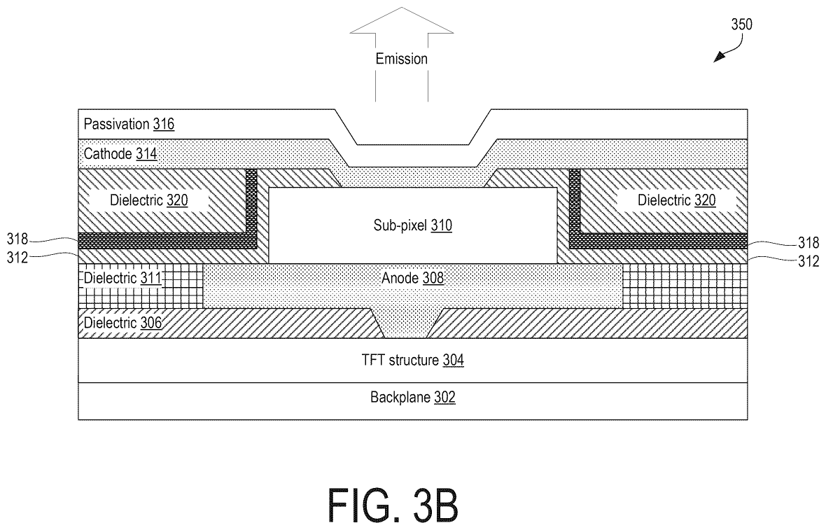

FIGS. 3A-3B and 4-5 illustrate example uLED sub-pixel architectures 300, 400, 500 with reflecting sidewalls in accordance with embodiments of the present disclosure. In the example architectures shown, there are reflecting sidewalls (e.g., 318, 418, 518) around the sub-pixels, with a dielectric layer (e.g., 312, 412, 512) between the sub-pixels and the reflecting sidewalls. At least a portion of the reflecting sidewalls may be co-planar with the light emitting sub-pixel material of the architectures. For instance, in each of the examples shown, the reflecting sidewall layers run vertically along in parallel with a side surface of the sub-pixels.

The reflective layers may increase the amount of external emission and prevent light from mixing with adjacent sub-pixels. The increased emission may be due to one or more of: the full contact area at the top of the sub-pixel material (i.e., between the cathode and the sub-pixel material, which provides more connections to the sub-pixel constituent components and less resistance); fewer planar interfaces above the sub-pixel material and thus, fewer internal reflections (meaning larger emission efficiency), side-emissions being reflected eventually toward external emission (rather than into adjacent sub-pixels), and reduced/eliminated pixel-to-pixel light mixing due to reflective sidewall structures. In addition, these embodiments provide for a simplified stack which that fewer and more simple processing steps (e.g., no cathode lithography steps), similar to the embodiment shown in FIG. 2.

Referring to FIG. 3A, the example architecture 300 includes a backplane 302, TFT structure 304, dielectric layer 306, and anode 308, which are implemented in the same or similar manner to the same components (e.g., backplane 102, TFT structure 104, dielectric layer 106, and anode 108) described above. In addition, like the example shown in FIG. 2, the architecture 300 includes a planar/flat cathode 314 and passivation layer 316, which may each be implemented in the same or similar manner as the same components described above. However, the architecture 300 includes a dielectric layer 311 on the dielectric layer 306 (and co-planar with the anode 308) as well as a dielectric layer 312 on the dielectric layer 311 and the anode 308, and immediately adjacent to the sub-pixel 310. The various dielectric layers shown may be of the same or different materials in various embodiments.

The architecture 300 also includes a reflective layer 318 formed on the dielectric layer 312. The reflective layer 318 may include any suitable reflective material, such as a metal (e.g., silver or aluminum) or a material that is white (e.g., as described below). It will be understood that the reflective layer may be formed such that it surrounds the sub-pixel 310 when viewed from a top view. There is additionally another dielectric layer 320 on the reflective layer 318.

FIG. 3B illustrates an example architecture 350 that includes the same aspects as the architecture 300, but with its cathode 314 and passivation layer 316 being formed in a similar manner as shown in FIG. 1, with a via/trench structure above the sub-pixel 310.

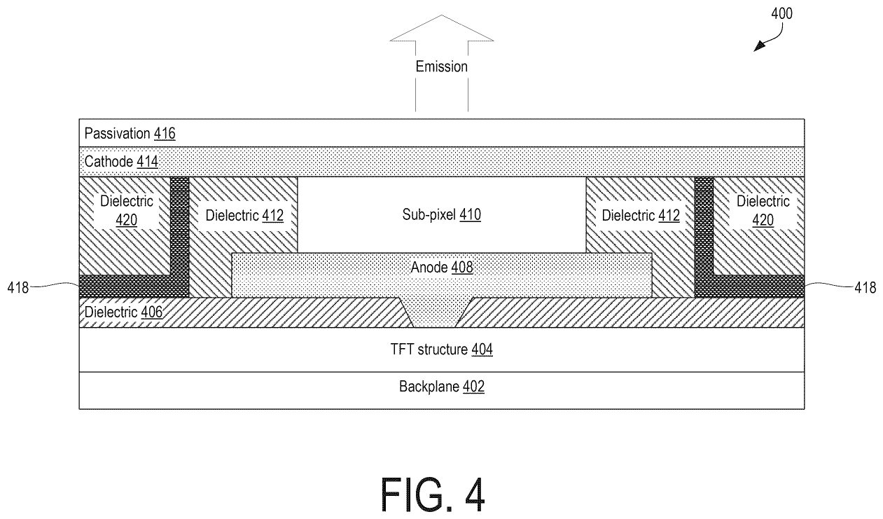

Referring now to FIG. 4, the example architecture 400 includes a backplane 402, TFT structure 404, dielectric layer 406, and anode 408, which are implemented in the same or similar manner to the same components (e.g., backplane 102, TFT structure 104, dielectric layer 106, and anode 108) described above. In addition, like the examples shown in FIGS. 2-3, the architecture 400 includes a planar/flat cathode 414 and passivation layer 416, which may each be implemented in the same or similar manner as the same components described above. However, in certain embodiments, the cathode 414 and passivation layer 416 may be formed with a via/trench structure above the sub-pixel 410, e.g., similar to the examples shown in FIGS. 1 and 3B.

Like the example shown in FIG. 3, the architecture 400 includes a dielectric layer 412 that is immediately adjacent to the sub-pixel 410. The dielectric layer 412 is formed partially on the dielectric layer 406 and the anode 408 as shown. The various dielectric layers shown may be of the same or different materials in various embodiments. There is additionally a reflective layer 418 formed on the dielectric layer 406 and adjacent the dielectric layer 412. The reflective layer 418 may include any suitable reflective material, such as a metal (e.g., silver or aluminum) or a material that is white (e.g., as described below). It will be understood that the reflective layer may be formed such that it surrounds the sub-pixel 410 when viewed from a top view. There is also another dielectric layer 420 on and adjacent the reflective layer 418.

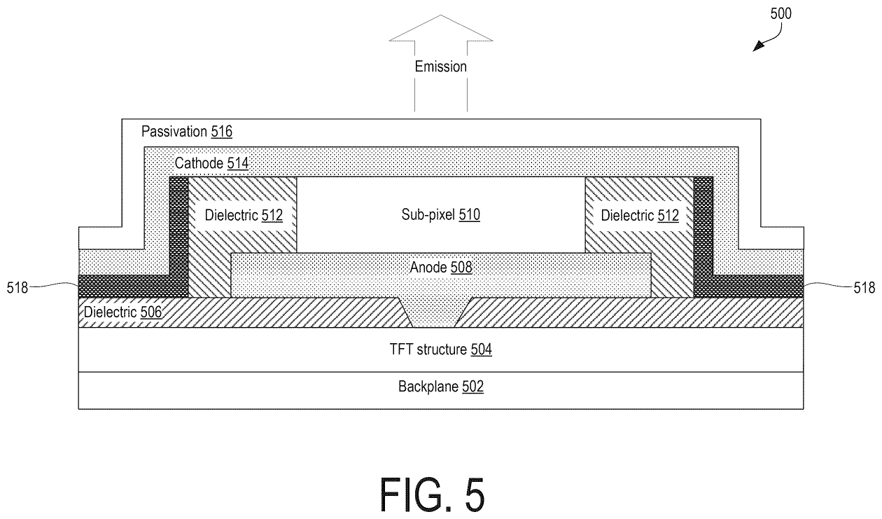

Referring to FIG. 5, the example architecture 500 includes a backplane 502, TFT structure 504, dielectric layer 506, and anode 508, which are implemented in the same or similar manner to the same components (e.g., backplane 102, TFT structure 104, dielectric layer 106, and anode 108) described above. Like the example shown in FIG. 4, the architecture 500 includes a dielectric layer 512 that is immediately adjacent to the sub-pixel 510. The dielectric layer 512 is formed partially on the dielectric layer 506 and the anode 508 as shown. The various dielectric layers shown may be of the same or different materials in various embodiments.

There is additionally a reflective layer 518 formed on the dielectric layer 506 and adjacent the dielectric layer 512. The reflective layer 518 may include any suitable reflective material, such as a metal (e.g., silver or aluminum) or a material that is white (e.g., as described below). It will be understood that the reflective layer may be formed such that it surrounds the sub-pixel 510 when viewed from a top view. In the example shown, the cathode 514 and passivation layer 516 are deposited on the existing structure (i.e., on the surfaces of the sub-pixel 510, dielectric 512, and reflective layer 518) such that they form a non-planar structure as shown. This can remove the fabrication step of depositing another dielectric layer (e.g., dielectric layer 420 of FIG. 4). However, in certain embodiments, the cathode 514 and passivation layer 516 may be formed with a via/trench structure above the sub-pixel 510, e.g., similar to the examples shown in FIGS. 1 and 3B.

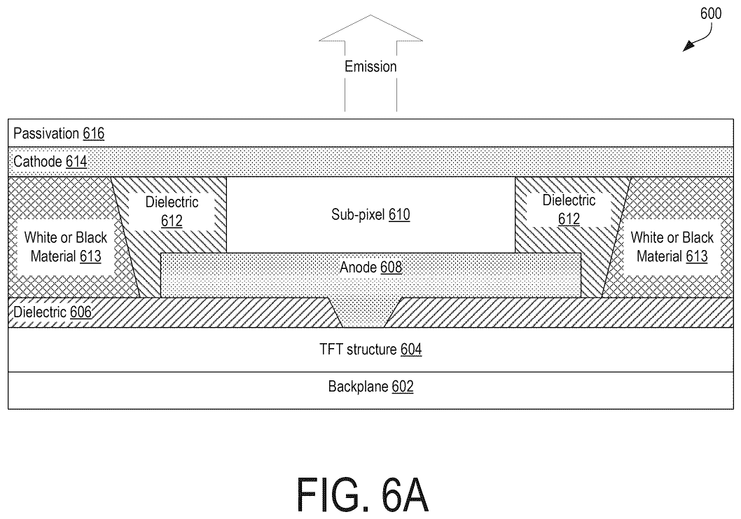

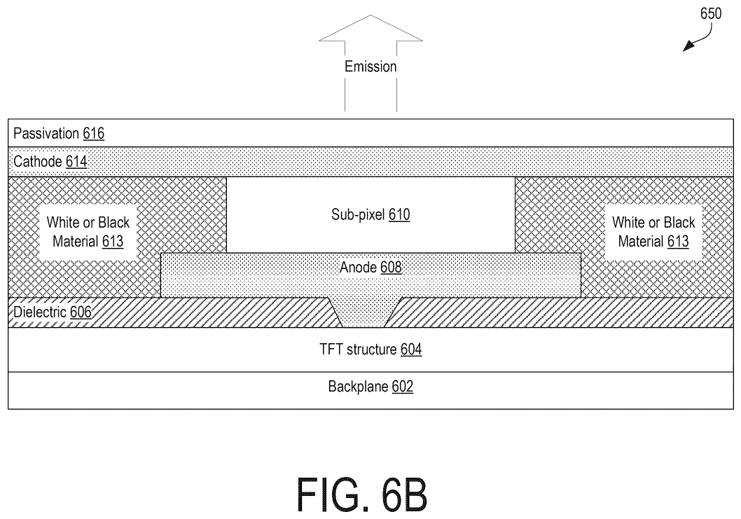

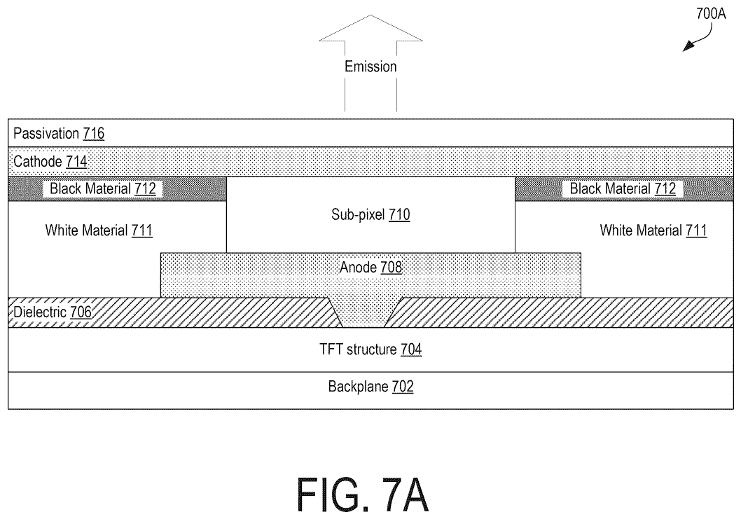

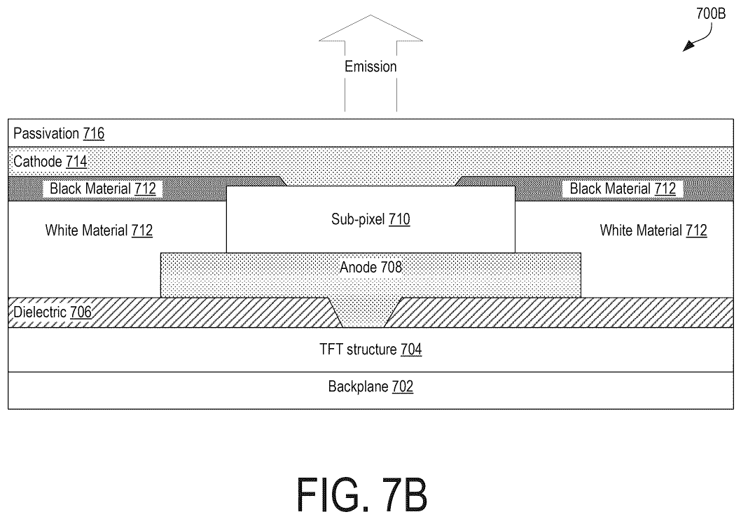

FIGS. 6A-6B and 7A-7B illustrate example uLED sub-pixel architectures 600, 700A, 700B with white or black material in accordance with embodiments of the present disclosure. In certain embodiments, the white or black material may be a photoresist (PR) material. The inclusion of the white or black materials can serve to prevent light from mixing with adjacent sub-pixels by either absorbing the light (e.g., in the case of the black PR) or reflecting the light (e.g., in the case of white PR). As used herein, a white material may refer to a material with a reflectance of greater than 65% for all visible light wavelengths, and a black material may refer to a material with an absorbance of greater than 65% for all visible light wavelengths. The white material may cause an increased emission due to it reflecting light from the sub-pixel, in a similar manner as described above with respect to the reflective layers, and pixel-to-pixel light mixing may be reduced by the white material reflecting light, the black material absorbing light, or both. The architectures shown may be manufactured with a simplified process flow as with the embodiments above, and with fewer overall stack layers.

Referring to FIG. 6A, the example architecture 600 includes a backplane 602, TFT structure 604, dielectric layer 606, and anode 608, which are implemented in the same or similar manner to the same components (e.g., backplane 102, TFT structure 104, dielectric layer 106, and anode 108) described above. In addition, like certain examples above, the architecture 600 includes a planar/flat cathode 614 and passivation layer 616, which may each be implemented in the same or similar manner as the same components described above. The architecture 600 further includes a dielectric layer 612 formed on the dielectric layer 606 and the anode 608, and immediately adjacent to the sub-pixel 610. The various dielectric layers shown may be of the same or different materials in various embodiments.

Additionally, there is a white or black material 613 on the dielectric layer 606 and immediately adjacent to the dielectric layer 612. The white/black material 613 may be a white/black photoresist material in certain embodiments. It will be understood that the dielectric layer 612 and white/black material 613 may be formed such that they surround the sub-pixel 610 when viewed from a top view. In embodiments where the material 613 is white, the material may act to reflect light in a similar manner as the reflective layers described above, which may allow for increased emission and decreased pixel-to-pixel light mixing. In embodiments where the material 613 is black, the material may act to absorb light from the sub-pixel 610 (and adjacent sub-pixels) to prevent pixel-to-pixel light mixing. Referring to the example shown in FIG. 6B, the example architecture 650 is the same as the architecture 600 of FIG. 6A, but without the dielectric material 612 between the white/black material 613 and the sub-pixel 610.

Although the examples shown in FIGS. 6A-6B are shown with a planar cathode 614 and passivation layer 616, in certain embodiments, the cathode 614 and passivation layer 616 may be formed with a via/trench structure above the sub-pixel 610, e.g., similar to the examples shown in FIGS. 1 and 3B.

Referring to FIGS. 7A-7B, the example architectures 700 include a backplane 702, TFT structure 704, dielectric layer 706, and anode 708, which are implemented in the same or similar manner to the same components (e.g., backplane 102, TFT structure 104, dielectric layer 106, and anode 108) described above. In addition, like certain examples above, the architecture 700 includes a planar/flat cathode 714 and passivation layer 716, which may each be implemented in the same or similar manner as the same components described above. The various dielectric layers shown may be of the same or different materials in various embodiments.

The architectures 700 further includes a white material layer 711 formed on the dielectric layer 706 and the anode 708, and immediately adjacent to at least a portion of the sub-pixel 710, as well as a black material layer 712 formed on the white material layer 711. The white material layer may serve to reflect light as previously described, while the black layer on top may serve to absorb light as previously described. In the example shown in FIG. 7A, a top surface of the black material layer 712 is level with a top surface of the sub-pixel 710. In contrast, in the example shown in FIG. 7B, the top surface of the black material layer 712 is partially on the top surface of the sub-pixel 710, and the cathode 714 is electrically connected though an opening (e.g., an etched opening) in the black material layer 712. The embodiment shown in FIG. 7B can provide some of the same advantages described with respect to FIG. 1, i.e., those relating to the dielectric layer 112 being on at least a portion of the top surface of the sub-pixel 110, while comparatively, the embodiment shown in FIG. 7A can provide certain advantages described above with respect to FIGS. 2-6, e.g., increased external emission, etc.

Although the examples shown in FIGS. 7A-7B are shown with a planar cathode 714 and passivation layer 716, in certain embodiments, the cathode 714 and passivation layer 716 may be formed with a via/trench structure above the sub-pixel 710, e.g., similar to the examples shown in FIGS. 1 and 3B.

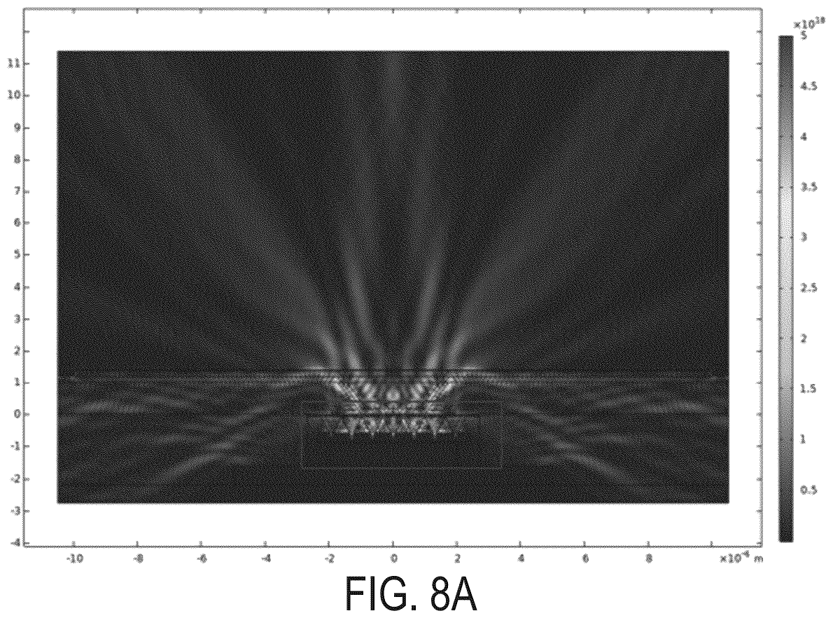

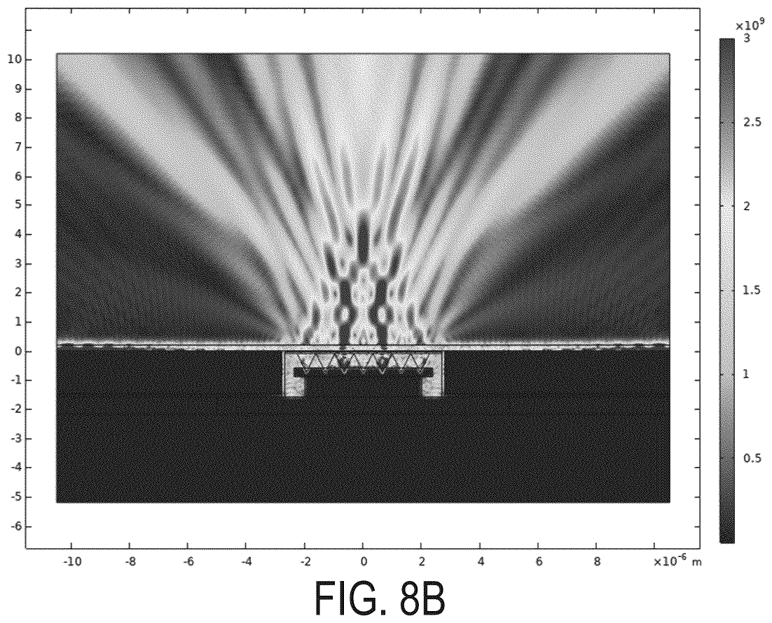

FIGS. 8A-8B illustrate example light emissions from a conventional uLED and a uLED with a reflective layer in accordance with embodiments herein, respectively. As is seen, certain sub-pixel light emissions propagate through the sides around the sub-pixel in the example shown in FIG. 8A. In contrast, the example shown in FIG. 8B illustrates the increased external emissions allowed by a reflective layer (or layer of white material) as described herein.

FIG. 9 is an example computing system comprising structures with LEDs electrically coupled to a mirror layer by vias or pillars. The computing system 900 comprises one or more processing units 904, a display 908, and a timing controller 912. The processing units 904 can comprise any type of processing unit described or referenced herein (e.g., an SoC) and can cause content to be displayed at the display 908. The processing units 904 can cause content (e.g., images, videos) to be displayed at the display 908 by generating video data that is provided to the timing controller 912. The timing controller 912 can convert the video data into signals that drive the display 908. The display 908 can comprise a plurality of pixels with individual pixels comprising one or more LEDs electrically coupled to a mirror layer by a via or pillar as described herein. The computing system 900 can further comprise a housing. In some embodiments, the display 908 and the one or more processing units 904 are located within the housing. In other embodiments, the one or more processing units 904 are located within the housing and the display 908 is a stand-alone display external to the housing and can communicate with the one or more processing units via a wired or wireless connection.

The technologies described herein can be performed by or implemented in any of a variety of computing systems, including mobile computing systems (e.g., smartphones, handheld computers, tablet computers, laptop computers, portable gaming consoles, 2-in-1 convertible computers, portable all-in-one computers), non-mobile computing systems (e.g., desktop computers, servers, workstations, stationary gaming consoles, set-top boxes, smart televisions, rack-level computing solutions (e.g., blade, tray, or sled computing systems)), and embedded computing systems (e.g., computing systems that are part of a vehicle, smart home appliance, consumer electronics product or equipment, manufacturing equipment). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

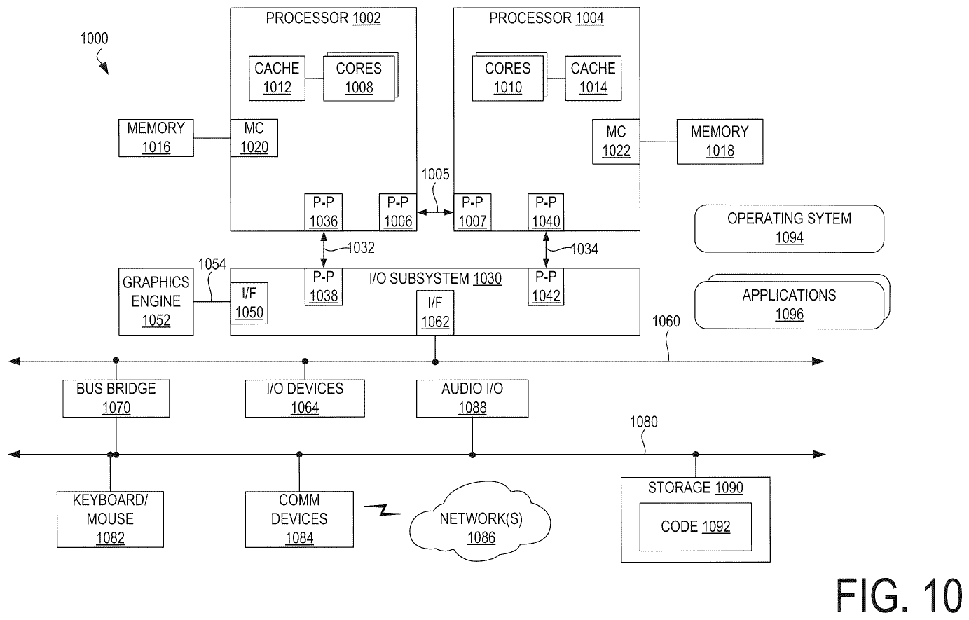

FIG. 10 is a block diagram of an example computing system in which technologies described herein may be implemented. Generally, components shown in FIG. 10 can communicate with other shown components, although not all connections are shown, for ease of illustration. The computing system 1000 is a multiprocessor system comprising a first processor unit 1002 and a second processor unit 1004 comprising point-to-point (P-P) interconnects. A point-to-point (P-P) interface 1006 of the processor unit 1002 is coupled to a point-to-point interface 1007 of the processor unit 1004 via a point-to-point interconnection 1005. It is to be understood that any or all of the point-to-point interconnects illustrated in FIG. 10 can be alternatively implemented as a multi-drop bus, and that any or all buses illustrated in FIG. 10 could be replaced by point-to-point interconnects. The processor units 1002 and 1004 comprise multiple processor cores. Processor unit 1002 comprises processor cores 1008 and processor unit 1004 comprises processor cores 1010.

Processor units 1002 and 1004 further comprise cache memories 1012 and 1014, respectively. The cache memories 1012 and 1014 can store data (e.g., instructions) utilized by one or more components of the processor units 1002 and 1004, such as the processor cores 1008 and 1010. The cache memories 1012 and 1014 can be part of a memory hierarchy for the computing system 1000. For example, the cache memories 1012 can locally store data that is also stored in a memory 1016 to allow for faster access to the data by the processor unit 1002. In some embodiments, the cache memories 1012 and 1014 can comprise multiple cache levels, such as level 1 (L1), level 2 (L2), level 3 (L3), level 4 (L4) and/or other caches or cache levels. In some embodiments, one or more levels of cache memory (e.g., L2, L3, L4) can be shared among multiple cores in a processor unit or among multiple processor units in an integrated circuit component. In some embodiments, the last level of cache memory on an integrated circuit component can be referred to as a last level cache (LLC). One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Although the computing system 1000 is shown with two processor units, the computing system 1000 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 1000 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 1002 and 1004 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Processor units 1002 and 1004 further comprise memory controller logic (MC) 1020 and 1022. As shown in FIG. 10, MCs 1020 and 1022 control memories 1016 and 1018 coupled to the processor units 1002 and 1004, respectively. The memories 1016 and 1018 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 1020 and 1022 are illustrated as being integrated into the processor units 1002 and 1004, in alternative embodiments, the MCs can be external to a processor unit.

Processor units 1002 and 1004 are coupled to an Input/Output (I/O) subsystem 1030 via point-to-point interconnections 1032 and 1034. The point-to-point interconnection 1032 connects a point-to-point interface 1036 of the processor unit 1002 with a point-to-point interface 1038 of the I/O subsystem 1030, and the point-to-point interconnection 1034 connects a point-to-point interface 1040 of the processor unit 1004 with a point-to-point interface 1042 of the I/O subsystem 1030. Input/Output subsystem 1030 further includes an interface 1050 to couple the I/O subsystem 1030 to a graphics engine 1052. The I/O subsystem 1030 and the graphics engine 1052 are coupled via a bus 1054.

The Input/Output subsystem 1030 is further coupled to a first bus 1060 via an interface 1062. The first bus 1060 can be a Peripheral Component Interconnect Express (PCIe) bus or any other type of bus. Various I/O devices 1064 can be coupled to the first bus 1060. A bus bridge 1070 can couple the first bus 1060 to a second bus 1080. In some embodiments, the second bus 1080 can be a low pin count (LPC) bus. Various devices can be coupled to the second bus 1080 including, for example, a keyboard/mouse 1082, audio I/O devices 1088, and a storage device 1090, such as a hard disk drive, solid-state drive, or another storage device for storing computer-executable instructions (code) 1092 or data. The code 1092 can comprise computer-executable instructions for performing methods described herein. Additional components that can be coupled to the second bus 1080 include communication device(s) 1084, which can provide for communication between the computing system 1000 and one or more wired or wireless networks 1086 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 802.11 standard and its supplements).

In embodiments where the communication devices 1084 support wireless communication, the communication devices 1084 can comprise wireless communication components coupled to one or more antennas to support communication between the computing system 1000 and external devices. The wireless communication components can support various wireless communication protocols and technologies such as Near Field Communication (NFC), IEEE 802.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM), and 5G broadband cellular technologies. In addition, the wireless modems can support communication with one or more cellular networks for data and voice communications within a single cellular network, between cellular networks, or between the computing system and a public switched telephone network (PSTN).

The system 1000 can comprise removable memory such as flash memory cards (e.g., SD (Secure Digital) cards), memory sticks, Subscriber Identity Module (SIM) cards). The memory in system 1000 (including caches 1012 and 1014, memories 1016 and 1018, and storage device 1090) can store data and/or computer-executable instructions for executing an operating system 1094 and application programs 1096. Example data includes web pages, text messages, images, sound files, and video data to be sent to and/or received from one or more network servers or other devices by the system 1000 via the one or more wired or wireless networks 1086, or for use by the system 1000. The system 1000 can also have access to external memory or storage (not shown) such as external hard drives or cloud-based storage.

The operating system 1094 can control the allocation and usage of the components illustrated in FIG. 10 and support the one or more application programs 1096. The application programs 1096 can include common computing system applications (e.g., email applications, calendars, contact managers, web browsers, messaging applications) as well as other computing applications.

In some embodiments, a hypervisor (or virtual machine manager) operates on the operating system 1094 and the application programs 1096 operate within one or more virtual machines operating on the hypervisor. In these embodiments, the hypervisor is a type-2 or hosted hypervisor as it is running on the operating system 1094. In other hypervisor-based embodiments, the hypervisor is a type-1 or “bare-metal” hypervisor that runs directly on the platform resources of the computing system 1094 without an intervening operating system layer.

In some embodiments, the applications 1096 can operate within one or more containers. A container is a running instance of a container image, which is a package of binary images for one or more of the applications 1096 and any libraries, configuration settings, and any other information that one or more applications 1096 need for execution. A container image can conform to any container image format, such as Docker®, Appc, or LXC container image formats. In container-based embodiments, a container runtime engine, such as Docker Engine, LXU, or an open container initiative (OCI)-compatible container runtime (e.g., Railcar, CRI-O) operates on the operating system (or virtual machine monitor) to provide an interface between the containers and the operating system 1094. An orchestrator can be responsible for management of the computing system 1000 and various container-related tasks such as deploying container images to the computing system 1094, monitoring the performance of deployed containers, and monitoring the utilization of the resources of the computing system 1094.

The computing system 1000 can support various additional input devices, such as a touchscreen, microphone, monoscopic camera, stereoscopic camera, trackball, touchpad, trackpad, proximity sensor, light sensor, electrocardiogram (ECG) sensor, PPG (photoplethysmogram) sensor, galvanic skin response sensor, and one or more output devices, such as one or more speakers or displays. A display can comprise any of the LED structures described herein. Other possible input and output devices include piezoelectric and other haptic I/O devices. Any of the input or output devices can be internal to, external to, or removably attachable with the system 1000. External input and output devices can communicate with the system 1000 via wired or wireless connections.

In addition, the computing system 1000 can provide one or more natural user interfaces (NUIs). For example, the operating system 1094 or applications 1096 can comprise speech recognition logic as part of a voice user interface that allows a user to operate the system 1000 via voice commands. Further, the computing system 1000 can comprise input devices and logic that allows a user to interact with computing the system 1000 via body, hand, or face gestures.

The system 1000 can further include at least one input/output port comprising physical connectors (e.g., USB, IEEE 1394 (Fire Wire), Ethernet, RS-232), a power supply (e.g., battery), a global satellite navigation system (GNSS) receiver (e.g., GPS receiver); a gyroscope; an accelerometer; and/or a compass. A GNSS receiver can be coupled to a GNSS antenna. The computing system 1000 can further comprise one or more additional antennas coupled to one or more additional receivers, transmitters, and/or transceivers to enable additional functions.

In addition to those already discussed, integrated circuit components, integrated circuit constituent components, and other components in the computing system 794 can communicate with interconnect technologies such as Intel® QuickPath Interconnect (QPI), Intel® Ultra Path Interconnect (UPI), Computer Express Link (CXL), cache coherent interconnect for accelerators (CCIX®), serializer/deserializer (SERDES), Nvidia® NVLink, ARM Infinity Link, Gen-Z, or Open Coherent Accelerator Processor Interface (OpenCAPI). Other interconnect technologies may be used and a computing system 794 may utilize more or more interconnect technologies. Any of the LED structures described herein can be incorporated into an optical interconnect.

It is to be understood that FIG. 10 illustrates only one example computing system architecture. Computing systems based on alternative architectures can be used to implement technologies described herein. For example, instead of the processors 1002 and 1004 and the graphics engine 1052 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 10. Moreover, the illustrated components in FIG. 10 are not required or all-inclusive, as shown components can be removed and other components added in alternative embodiments.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an apparatus comprising: a thin film transistor (TFT) structure layer; a dielectric layer on the TFT structure layer; an anode on the dielectric layer and in electrical connection with the TFT structure layer; a light emitting material on the anode; a layer comprising a reflective material surrounding the light emitting material; and a cathode on the light emitting material.

Example 2 includes the subject matter of Example 1, wherein the layer comprising the reflective material is a metal layer.

Example 3 includes the subject matter of Example 1 or 2, wherein at least a portion of the layer comprising the reflective material is co-planar with the light emitting material.

Example 4 includes the subject matter of any one of Examples 1-3, wherein the cathode is planar.

Example 5 includes the subject matter of any one of Examples 1-4, wherein the

dielectric layer is a first dielectric layer, and the apparatus further comprises a second dielectric layer between the light emitting material and the layer comprising the reflective material.

Example 6 includes the subject matter of Example 5, wherein the apparatus includes a

third dielectric layer on the first dielectric layer and co-planar with the anode, the second dielectric layer is on the third dielectric layer and a portion of the anode, and the layer comprising the reflective material is on the second dielectric layer.

Example 7 includes the subject matter of Example 5, wherein the second dielectric

layer is on the first dielectric layer and a portion of the anode, and the layer comprising the reflective material is on the first dielectric layer.

Example 8 includes the subject matter of Example 7, further comprising a third dielectric layer on the layer comprising the reflective material.

Example 9 includes the subject matter of Example 7, wherein the cathode is on the layer comprising the reflective material is on the first dielectric layer.

Example 10 is an apparatus comprising: a thin film transistor (TFT) structure layer; a dielectric layer on the TFT structure layer; an anode on the dielectric layer and in electrical connection with the TFT structure layer; a light emitting material on the anode; a white material layer (e.g., a white photoresist material) surrounding the light emitting material; and a cathode on the light emitting material.

Example 11 includes the subject matter of Example 10, wherein at least a portion of the white material layer is co-planar with the light emitting material.

Example 12 includes the subject matter of Example 10 or 11, wherein the cathode is planar.

Example 13 includes the subject matter of any one of Examples 10-12, further comprising a black material layer (e.g., a black photoresist material) on the white material layer.

Example 14 includes the subject matter of Example 13, wherein a top surface of the black material layer is level with a top surface of the light emitting material and the cathode is on the black material layer.

Example 15 includes the subject matter of Example 13, wherein the black material layer is on a portion of a top surface of the light emitting material and the cathode is on the black material layer.

Example 16 includes the subject matter of any one of Examples 10-12, wherein the dielectric layer is a first dielectric layer, and the apparatus further comprises a second dielectric layer between the light emitting material and the white material layer.

Example 17 includes the subject matter of Example 16, wherein the second dielectric layer is on the first dielectric layer and a portion of the anode, and the white material layer is on the first dielectric layer.

Example 18 is an apparatus comprising: a thin film transistor (TFT) structure layer; a dielectric layer on the TFT structure layer; an anode on the dielectric layer and in electrical connection with the TFT structure layer; a light emitting material on the anode; a black material layer (e.g., a black photoresist material) surrounding the light emitting material; and a cathode on the light emitting material.

Example 19 includes the subject matter of Example 18, wherein at least a portion of the black material layer is co-planar with the light emitting material.

Example 20 includes the subject matter of Example 18 or 19, wherein the cathode is planar.

Example 21 includes the subject matter of any one of Examples 18-20, wherein the dielectric layer is a first dielectric layer, and the apparatus further comprises a second dielectric layer between the light emitting material and the black material layer.

Example 22 includes the subject matter of Example 21, wherein the second dielectric layer is on the first dielectric layer and a portion of the anode, and the black material layer is on the first dielectric layer.

Example 23 includes a device comprising a plurality of pixels, each pixel comprising a set of sub-pixels, each sub-pixel according to any of the previous examples.

Example 24 includes a computing device comprising a timing controller and display according to Example 23.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1-25. (canceled)

26. An apparatus comprising:
a thin film transistor (TFT) structure layer;
a dielectric layer on the TFT structure layer;
an anode on the dielectric layer and in electrical connection with the TFT structure layer;
a light emitting material on the anode;
a layer comprising a reflective material surrounding the light emitting material; and
a cathode on the light emitting material.

27. The apparatus of claim 26, wherein the layer comprising the reflective material is a metal layer.

28. The apparatus of claim 26, wherein at least a portion of the layer comprising the reflective material is co-planar with the light emitting material.

29. The apparatus of claim 26, wherein the cathode is planar.

30. The apparatus of claim 26, wherein the dielectric layer is a first dielectric layer, and the apparatus further comprises a second dielectric layer between the light emitting material and the layer comprising the reflective material.

31. The apparatus of claim 30, wherein the apparatus includes a third dielectric layer on the first dielectric layer and co-planar with the anode, the second dielectric layer is on the third dielectric layer and a portion of the anode, and the layer comprising the reflective material is on the second dielectric layer.

32. The apparatus of claim 30, wherein the second dielectric layer is on the first dielectric layer and a portion of the anode, and the layer comprising the reflective material is on the first dielectric layer.

33. The apparatus of claim 32, further comprising a third dielectric layer on the layer comprising the reflective material.

34. The apparatus of claim 32, wherein the cathode is on the layer comprising the reflective material is on the first dielectric layer.

35. An apparatus comprising:
a thin film transistor (TFT) structure layer;
a dielectric layer on the TFT structure layer;
an anode on the dielectric layer and in electrical connection with the TFT structure layer;
a light emitting material on the anode;
a white material layer surrounding the light emitting material; and
a cathode on the light emitting material.

36. The apparatus of claim 35, wherein at least a portion of the white material layer is co-planar with the light emitting material.

37. The apparatus of claim 35, wherein the cathode is planar.

38. The apparatus of claim 35, wherein the white material layer is a white photoresist material.

39. The apparatus of claim 35, further comprising a black material layer on the white material layer.

40. The apparatus of claim 39, wherein a top surface of the black material layer is level with a top surface of the light emitting material and the cathode is on the black material layer.

41. The apparatus of claim 39, wherein the black material layer is on a portion of a top surface of the light emitting material and the cathode is on the black material layer.

42. The apparatus of claim 39, wherein the black material layer is a black photoresist material.

43. The apparatus of claim 35, wherein the dielectric layer is a first dielectric layer, and the apparatus further comprises a second dielectric layer between the light emitting material and the white material layer.

44. The apparatus of claim 43, wherein the second dielectric layer is on the first dielectric layer and a portion of the anode, and the white material layer is on the first dielectric layer.

45. An apparatus comprising:
a thin film transistor (TFT) structure layer;
a dielectric layer on the TFT structure layer;
an anode on the dielectric layer and in electrical connection with the TFT structure layer;
a light emitting material on the anode;
a black material layer surrounding the light emitting material; and
a cathode on the light emitting material.

46. The apparatus of claim 45, wherein the black material layer is a black photoresist material.

47. The apparatus of claim 45, wherein at least a portion of the black material layer is co-planar with the light emitting material.

48. The apparatus of claim 45, wherein the cathode is planar.

49. The apparatus of claim 45, wherein the dielectric layer is a first dielectric layer, and the apparatus further comprises a second dielectric layer between the light emitting material and the black material layer.

50. The apparatus of claim 49, wherein the second dielectric layer is on the first dielectric layer and a portion of the anode, and the black material layer is on the first dielectric layer.
